(19) United States
(12) Patent Application Publication
(10) Pub. No.: US 2009/0152103 A1
(43) Pub. Date: Jun. 18, 2009

(54) Sputtering apparatus and method of manufacturing flat display device using the sputtering apparatus

(76) Inventor: Kyoung-Won Nam, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 12/230,596

(22) Filed: Sep. 2, 2008

(30) Foreign Application Priority Data
Dec. 13, 2007 (KR) 10-2007-0129954

(51) Int. Cl. C23C 14/00

(52) U.S. Cl. 204/192.29; 204/298.11

(57) ABSTRACT

Provided is a sputtering apparatus which can check a short-circuit of a mask during a non-discharge period, the sputtering apparatus including: a substrate support, which is installed inside a chamber and supports a substrate; a target, which includes a target material that is to be deposited on the substrate; a mask, which is spaced apart from the substrate so as to surround the peripheral part of the substrate; a shield, which supports the mask and is connected to ground; an insulating member, which combines the mask and the shield and includes an insulating material; and a short-circuit detecting apparatus for detecting a short-circuit of the mask during a non-discharge period of the sputtering apparatus.

### CROSS-REFERENCE TO RELATED PATENT APPLICATION AND CLAIM OF PRIORITY

This application claims the benefit of Korean Patent Application No. 10-2007-0129954, filed on Dec. 13, 2007, in the Korean Intellectual Property Office, the disclosure of which is incorporated herein in its entirety by reference.

### BACKGROUND OF THE INVENTION

1. Field of the Invention

The present invention relates to a sputtering apparatus, and more particularly, to a sputtering apparatus which can check a short circuit of a mask during a non-discharge period, and a method of manufacturing a flat display device using the sputtering apparatus.

2. Description of the Related Art

A sputtering method wherein particles of a target material are ejected due to physical collision of ion particles is widely used for forming an inorganic film, such as a metal film or a transparent conductive film.

When using a sputtering apparatus, ion particles that collide with a source target are produced by exciting plasma in a chamber. This process will now be described in detail. First, the chamber is highly vacuummized, and sputtering gas at low pressure, generally argon (Ar) or other reactive gas, is inserted into the chamber. Thus, Ar atoms are ionized as free electrons which are ejected and accelerated from a cathode collide with the Ar atoms by applying a direct current (DC) or operating a radio frequency (RF) power source between two electrodes connected to a source target and a substrate. Electrons ejected as the Ar ions are formed and electrons supplied from an electrode continuously are accelerated and collide so as to form more ions. Electrons are annihilated due to electron-ion recombination and collision with the electrode and the inner wall of the chamber. When the numbers of free electrons generated and annihilated are the same, plasma can be formed in a stable equilibrium state. Since a cathode plate covered with the target material maintains a negative potential compared to the substrate, the Ar ions, which are positive charges, are accelerated towards the source target and collide with the source target. Here, each Ar ion has energy as much as hv where h is the Planck's constant and v is the frequency, and the energy is transferred to the target when the Ar ions and the target collide. Also, only when the coherence of elements forming the target and a work function of the electrons reach a predetermined level, the target material is ejected in a vapor form so as to be deposited on the substrate.

Such sputtering apparatus is widely used to form a film of a flat display device, such as a thin film transistor liquid crystal display (TFT LCD) or an organic electroluminescent display device, and an electronic device. Since a substrate of the flat display device used in such a film formation process is an insulator such as glass, the surface of the substrate is charged by electrons in the plasma, and thus has a floating potential of tens of volts. Accordingly, if a part of the surface of the film contacts Earth potential, electric charges on the surface of the film turn into current and thus a discharge trace such as a crater is formed in the contacted region, which greatly damages the film.

Accordingly, a conventional sputtering apparatus maintains an insulating state of a mask that is disposed near a substrate, by combining the mask to a shield, which is electrically connected to ground, via an insulating member. However, if the operating time of the sputtering apparatus is extended, a metal film is adhered to most members in a discharge space of the chamber. Moreover, the metal film is adhered to the insulating member disposed between the shield and the mask. In this case, the mask and the insulating member are electrically conducted, and thus the mask is short-circuited. Accordingly, the mask should be periodically checked whether it stays in the insulating state. The short-circuit of the mask is determined by using a method of measuring a voltage that is charged to the mask while forming a film, for example, it is determined that the mask is short-circuited when the voltage of the mask is 0.

However, in the conventional sputtering apparatus, even if the voltage applied to the mask is 0 while operating the chamber, it is unclear whether such phenomenon is due to the short-circuit between the insulating member and the mask, or due to another reason inside the chamber. Also, when the film formation process is repeatedly performed in one chamber, it is unclear whether the short-circuit between the mask and the insulating member is generated during the film formation process or before the film formation process. Accordingly, when a short-circuit is already generated between the insulating member and the mask before a new film formation process, an unnecessary additional film formation process is performed, and thus time and raw materials are wasted.

### SUMMARY OF THE INVENTION

The present invention provides an improved sputtering apparatus.

The present invention provides a method of manufacturing a flat display device using the sputtering apparatus.

The present invention provides a sputtering apparatus which can detect whether a mask is short-circuited even during a non-discharge period, and a method of manufacturing a flat display device using the sputtering apparatus.

According to an aspect of the present invention, there is provided a sputtering apparatus including: a chamber; a substrate support installed in the chamber for supporting a substrate; a target installed in the chamber, the target including a target material to be deposited on the substrate and a target support supporting the target material; a mask spaced apart from the substrate to mask the peripheral portion of the substrate; a shield shielding a peripheral portion of the substrate support from deposition from the target material, the shield connected to ground; an electrical insulating member linking the mask and the shield and electrically insulating the mask from the shield; and a short-circuit detecting apparatus connected to the mask, the short-circuit detecting apparatus detecting a short-circuit of the mask during a non-discharge period of the sputtering apparatus.

The short-circuit detecting apparatus may include a power supplier, which supplies a predetermined power to the mask only during the non-discharge period of the sputtering apparatus.

The short-circuit detecting apparatus may further include a switch, which electrically connects the power supplier and the mask only during the non-discharge period.

The short-circuit detecting apparatus may detect the short-circuit of the mask by measuring a voltage in a predetermined region between the mask and the power supplier.

The short-circuit detecting apparatus may detect the short-circuit of the mask by measuring a current between the mask and the power supplier.

The short-circuit detecting apparatus may further include a display device, which includes a display screen that can display a value of the measured voltage or current to an operator.

The short-circuit detecting apparatus may further include an alarm, which outputs an alarm sound when the value of the measured voltage or current is in a predetermined range.

The short-circuit detecting apparatus may further include a light emitter, which emits light when the value of the measured voltage or current is in a predetermined range.

The shield may be disposed to surround an outer region of the mask.

According to another aspect of the present invention, there is provided a method of manufacturing a flat display device by using the sputtering apparatus of above.

The flat display device may be an organic electroluminescent device.

The flat display device may be a liquid crystal display.

According to an aspect of the present invention, there is provided a sputtering apparatus including: a chamber; a substrate support installed in the chamber for supporting a substrate; a target installed in the chamber, the target including a target material to be deposited on the substrate and a target support supporting the target material; a first power supplier providing a negative voltage to the target support; a mask spaced apart from the substrate to mask the peripheral portion of the substrate; a shield shielding a peripheral portion of the substrate support from deposition from the target material, the shield connected to ground; an electrical insulating member linking the mask and the shield and electrically insulating the mask from the shield; and a short-circuit detecting apparatus connected to the mask, the short-circuit detecting apparatus including a second power supplier to supply a predetermined power to the mask during a non-discharge period and detecting the short-circuit of the mask by measuring a voltage drop or a current change between the mask and the second power supplier.

According to an aspect of the present invention, there is provided a sputtering apparatus including: a chamber; a substrate support installed in the chamber for supporting a substrate; a target installed in the chamber, the target including a target material to be deposited on the substrate and a target support supporting the target material; a mask spaced apart from the substrate to mask the peripheral portion of the substrate; a shield shielding a peripheral portion of the substrate support from deposition from the target material, the shield connected to ground; an electrical insulating member linking the mask and the shield and electrically insulating the mask from the shield; and a short-circuit detecting apparatus connected to the mask, the short-circuit detecting apparatus including: a power supplier supplying a predetermined power to the mask; a switch turned on to electrically connect the power supplier and the mask during a discharge period of the sputtering apparatus and turned off to electrically disconnect the power supplier and the mask during a non-discharge period of the sputtering apparatus; and a detector detecting a voltage or a current between the mask and the power supplier during the non-discharge period to determine the short-circuit of the mask.

According to another aspect of the present invention, the short-circuit detecting apparatus in the sputtering apparatus directly measures a voltage charged to the mask during the discharge period to determine the short-circuit of the mask.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a sputtering apparatus according to an embodiment of the present invention; and

FIG. 2 is a diagram illustrating in detail a short-circuit detecting apparatus for detecting a short-circuit in a mask.

### DETAILED DESCRIPTION OF THE INVENTION

Hereinafter, the present invention will be described more fully with reference to the accompanying drawings, in which exemplary embodiments of the invention are shown.

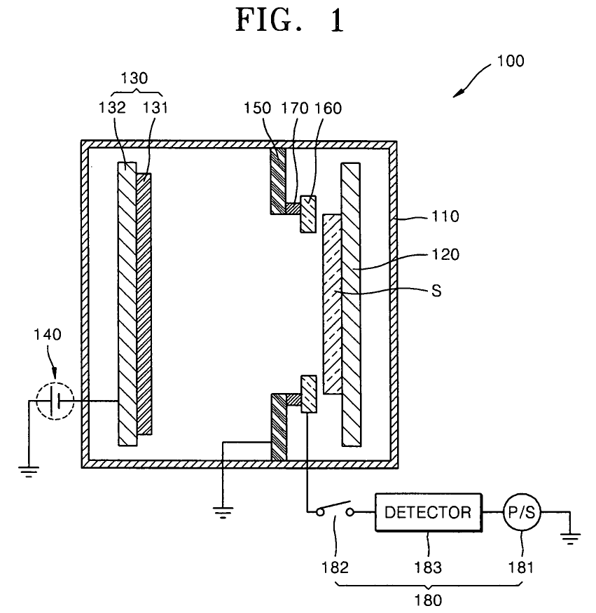

FIG. 1 is a cross-sectional view illustrating a sputtering apparatus 100 according to an embodiment of the present invention.

Referring to FIG. 1, the sputtering apparatus 100 includes a substrate support 120, a target 130, a shield 150, a mask 160, and an insulating member 170 inside a chamber 110, and a short-circuit detecting apparatus 180 for detecting a short circuit of the mask 160.

The chamber 110 is a vacuum chamber, and maintains a vacuum degree of approximately 10⁻⁸ Torr. Also, although not illustrated in FIG. 1, the chamber 110 may include a sputtering gas inlet/outlet (not shown), so that a sputtering gas, such as argon (Ar), flows into the chamber 110 through the sputtering gas inlet or flows out of the chamber 110 through the sputtering gas outlet.

The substrate support 120 supports a substrate S that is loaded into the chamber 110 for metal thin film deposition. The configuration and the location of the substrate support 120 may vary. For example, the substrate support 120 may include an element that has a hinge shaft at one side and can horizontally receive the substrate S inserted through a gate (not shown) on one side of the chamber 110 and vertically rotate the received substrate S.

The target 130 includes a sputtering target (i.e., target material) 131, which is formed of a material to be deposited on the substrate S, and a target support 132 such as a backplate, which supports the target 131.

The sputtering target 131 is formed of a material including a metal or the like that is to be deposited on the substrate S. For example, when manufacturing an organic electroluminescent display device, the sputtering target 131 may include various metals, such as aluminum (Al), molybdenum (Mo), copper (Cu), gold (Au), and platinum (Pt), for forming a source, drain, or gate electrode of a thin film transistor of the organic electroluminescent display device, or indium-tin-oxide (ITO), for forming a film of an anode or a common electrode of an organic electroluminescent film.

Although only one sputtering target 131 is illustrated in FIG. 1 according to the current embodiment of the present invention, the sputtering target 131 may include more than one sputtering target 131. For example, when two sputtering targets 131 are included, each sputtering target 131 may be formed of different materials so as to variously control the materials deposited on the substrate S.

The target support 132 supports the sputtering target 131, and in some cases, the target support 132 may support and rotate the sputtering target 131.

The target support 132 acts as a cathode during a plasma discharge by receiving a negative (−) voltage from a first power supplier 140. The power source supplied by the first power supplier 140 is a direct current (DC) power source in FIG. 1, but the power source is not limited thereto, and may be radio a frequency (RF) power source or a DC pulse power source.

Although not illustrated in detail in FIG. 1, the target 130 may include a magnetic field generating member such as a magnet so as to increase the thin film deposition rate. Such a magnet which may be installed behind the target support 132, between the target support 132 and the target material 131 or on the sputtering target 131. According to an embodiment of the present invention, when the magnet is installed on the target material, the magnet may generate a magnetic field while rotating when the thin film deposition process is performed.

The shield 150 supports the mask 160 and shields a part of the sputtering target 131 and the substrate support 120.

The shield 150 is formed of an electric conductive material, such as Al, and acts as an anode during the plasma discharge by being connected to ground.

The shield 150 is disposed so as to protect the inner wall of the chamber 110 including the surface of the mask 160. Accordingly, the shield 150 can prevent a metal material of the sputtering target 131 spurted by the Ar gas from being deposited on the inner wall of the chamber 110.

The mask is spaced apart from the substrate S and covers the peripheral portion of the substrate S. Accordingly, the metal material spurted by the sputtering target 131 is not deposited on the peripheral portion of the substrate S. When the peripheral portion of the substrate S is deposited with the metal material, the surface of the film formed on the substrate may be damaged while the substrate S is being moved to the outside of the chamber 110 or the metal material of the film on the substrate S is being etched in a pattern. Accordingly, the peripheral portion of the substrate S is left as a non-film region.

The mask 160 is formed of an electric conductive material, such as titanium. As described above, a defect such as a crater may be left on the surface of the film as the mask 160 touches or is adjacent to the substrate S during the film formation. Accordingly, the mask 160 should always be in a floating state. Thus, the mask 160 is electrically insulated from the shield 150.

The insulating member 170 formed of a material having a high electric insulating property is positioned between the shield 150 and the mask 160.

The insulating member 170 combines the shield 150 and the mask 160, and electrically insulates the mask 160 form the shield 150 that is connected to ground. However, when the operating time of the sputtering apparatus 100 is extended, a metal film may be formed on most members including the insulating member 170 in a discharge space of the chamber 110. If the metal film is formed on the insulating member 170, the mask 160 is short-circuited by the metal film adhered on the insulating member 170.

In a conventional sputtering apparatus, a short-circuit of a mask is determined by measuring a voltage charged to the mask while forming a film by using a voltmeter connected to the mask. However, as described above, it is not clear whether the short circuit of the mask is due to a short circuit between the insulating member and the mask. It is also not clear whether the short circuit occurs while forming the film.

Accordingly, the sputtering apparatus 100 according to an embodiment of the present invention includes a short-circuit detector 180 that can check the short-circuit of the mask 160 even when the sputtering apparatus 100 does not perform a discharging operation.

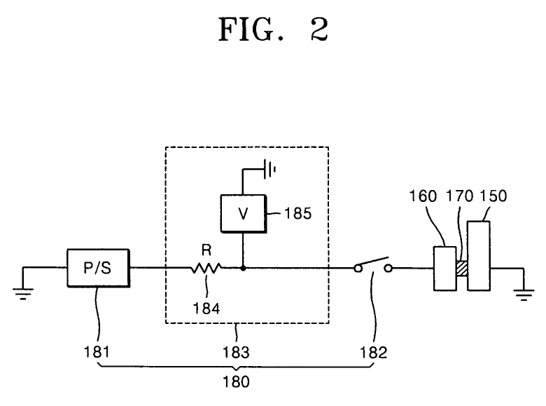

FIG. 2 is a diagram illustrating in detail the short-circuit detecting apparatus 180.

Referring to FIG. 2, the short-circuit detecting apparatus 180 includes a second power supplier 181, which applies a predetermined power to the mask 160 only during the non-discharge of the sputtering apparatus 100, a switch 182, and a detector 183,

The second power supplier 181 supplies the predetermined power to the mask 160, and one end of the second power supplier 181 is grounded. The power supplied by the second power supplier 181 may be DC or AC power, and in the current embodiment, DC power of approximately 60 mA and 24 V is applied to the mask 160 by using SMD-950 of ULVAC.

When the first power supplier 140 does not supply power to the target, i.e., when plasma discharge does not take place in the sputtering apparatus 100, the switch 182 electrically connects the second power supplier 181 and the mask 160. The operation of the switch 182 may be pre-programmed, but may be directly performed by an operator. Since an error may occur inside the chamber 110 if the power from the second power supplier 181 is directly supplied to the mask 160 while the plasma discharge is being performed, it is preferred that the power from the second power supplier 181 is not directly supplied to the mask 160.

When the switch 182 is turned on and the power of the second power supplier 181 is applied to the mask 160, the detector 183 determines the short-circuit of the mask 160 by checking the change of a voltage or current value between the second power supplier 181 and the mask 160.

The detector 183 includes a predetermined resistor 184, which is installed between the second power supplier 181 and the switch 182, and a voltmeter 185, which measures a voltage drop of a voltage from the second power supplier 181 to the resistor 184.

Although only one resistor 184 is illustrated in FIG. 2, more that one resistor 184 may be used. Also, instead of the voltmeter 185 for detecting a voltage, an ammeter (not shown) for detecting a current flowing between the second power supplier 181 and the mask 160 may be included.

Also, the detector 183 may include a display device (not shown), which includes a display screen that can display a value of voltage or current detected by the detector 183.

The short-circuit detecting apparatus 180 may include an alarm (not shown), which outputs an alarm sound when the value of the voltage or current measured by the detector 183 is in a predetermined range, for example, when the detected voltage is lower than or equal to 5 V. Also, the short-circuit detecting apparatus 180 may include an electroluminescent device (not shown), such as an LED.

According to the short-circuit detecting apparatus 180 including the voltmeter 185, the short-circuit of the mask 160 is detected as follows. The following description is an example of the short-circuit detection, but the present invention is not limited to the following example.

First, when the sputtering apparatus 100 does not perform the film formation process, i.e., during a non-discharge period of the sputtering apparatus 100, the switch 182 is turned off so that the second power supplier 181 supplies power to the mask 160. At this time, when a voltage measured by the voltmeter 185 is 24 V, it is determined that the mask 160 is in a floating state. Alternatively, when the voltage measured by the voltmeter 185 is 0 V, it is determined that the mask 160 is short-circuited.

The voltage measured by the voltmeter 185 of the short-circuit detecting apparatus 180 may be between 0 V to 24 V. As the time for performing the plasma discharge increases, a resistance value of the mask 160 decreases. Accordingly, the value of the voltage detected by the voltmeter 185 decreases, and finally be 0 V.

As presented above, the development of the short-circuit of the mask 160 can be observed to some extent before the mask 160 is completely short-circuited. Accordingly, before the mask 160 is fully short-circuited, the operation of the sputtering apparatus 100 can be stopped at a suitable time so that the sputtering apparatus 100 can be checked and waste of raw materials can be prevented.

By using the sputtering apparatus 100, the short-circuit of the mask 160 is determined only during a non-discharge period, and thus the possibility of misjudging the short-circuit of the mask 160 due to other effects can be reduced. For example, when the sputtering apparatus 100 is used in a magnetron method, while forming a film, i.e., during a discharge, the mask 160 may be misjudged as being short-circuited since the electric potential of the mask 160 is affected by the magnetic field change as a permanent magnet or the a magnetic field generating member of the target 130 is moved. However, in the current embodiment, the voltage of the mask 160 is measured only during a non-discharge period, and thus, such external effects can be prevented.

Also, since the short-circuit of the mask 160 is determined before the film formation process or between the film formation processes, i.e., during the non-discharge of plasma, when the mask 160 is determined as being short-circuited, the following processes are not performed anymore. Accordingly, time and raw materials consumed can be significantly reduced.

The sputtering apparatus 100 including the short-circuit detecting apparatus 180 can be used not only for forming an electrode or an insulating film in a manufacturing method of an organic electroluminescent display device, but also for forming an electrode or an insulating film in a manufacturing method of a flat display device, such as a liquid crystal display.

In the sputtering apparatus 100 of FIG. 1, only one substrate S is installed inside the chamber 110, but the number of substrates S is not limited to one. Here, a plurality of masks 160 is included to correspond to a plurality of substrates S, and the short-circuit detecting apparatus 180 can be connected to each mask 160.

The sputtering apparatus 100 of according to one embodiment of the present invention includes the short-circuit detecting apparatus 180 that only operates during a non-discharge period, but this does not mean that the sputtering apparatus 100 cannot determine the short-circuit of the mask 160 by measuring voltage change of the mask 160 during the discharge like the conventional sputtering apparatus.

In other words, like the conventional sputtering apparatus, the sputtering apparatus 100 can measure the short circuit of the mask 160 by directly measuring the voltage charged into the mask 160 during the discharge, and also by supplying a predetermined power source to the mask 160 from the second power supplier 181 and measuring the changed voltage or current during the non-discharge.

The advantages of the present invention include, but are not limited to, at least one of the followings.

First, since a short-circuit of a mask can be measured before a film formation process or between film formation processes, the following processes are not performed when a short-circuit is detected. Accordingly, time and raw materials consumed can be significantly reduced.

Second, since a short-circuit of a mask is determined only during a non-discharge period, the possibility of misjudging that the mask is short-circuited due to other effects can be reduced.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A sputtering apparatus comprising:
a chamber;
a substrate support installed in the chamber for supporting a substrate;
a target installed in the chamber, the target comprising a target material to be
deposited on the substrate and a target support supporting the target material;
a mask spaced apart from the substrate to mask the peripheral portion of the substrate;
a shield shielding a peripheral portion of the substrate support from deposition from the target material, the shield connected to ground;
an electrical insulating member linking the mask and the shield and electrically insulating the mask from the shield; and
a short-circuit detecting apparatus connected to the mask, the short-circuit detecting apparatus detecting a short-circuit of the mask during a non-discharge period of the sputtering apparatus.

2. The sputtering apparatus of claim 1, wherein the short-circuit detecting apparatus comprises a power supplier supplying a predetermined power to the mask only during the non-discharge period of the sputtering apparatus.

3. The sputtering apparatus of claim 1, wherein the short-circuit detecting apparatus comprises a power supplier supplying a predetermined power to the mask and a switch electrically connecting the power supplier and the mask only during the non-discharge period of the sputtering apparatus.

4. The sputtering apparatus of claim 2, wherein the short-circuit detecting apparatus detects the short-circuit of the mask by measuring a voltage in a predetermined region between the mask and the power supplier.

5. The sputtering apparatus of claim 2, wherein the short-circuit detecting apparatus detects the short-circuit of the mask by measuring a current between the mask and the power supplier.

6. The sputtering apparatus of claim 1, wherein the short-circuit detecting apparatus further comprises a display device displaying a value of the measured voltage or current to an operator.

7. The sputtering apparatus of claim 3, wherein the short-circuit detecting apparatus further comprises an alarm outputting an alarm sound when the value of the measured voltage or current is in a predetermined range.

8. The sputtering apparatus of claim 3, wherein the short-circuit detecting apparatus further comprises a light emitter emitting light when the value of the measured voltage or current is in a predetermined range.

9. The sputtering apparatus of claim 1, wherein the shield is disposed to surround an outer region of the mask.

10. A method of manufacturing a flat display device, comprising forming a film of the flat panel display device by utilizing the sputtering apparatus of claim 1.

11. The method of claim 10, wherein the flat display device is an organic electroluminescent device.

12. The method of claim 10, wherein the flat display device is a liquid crystal display.

13. A sputtering apparatus comprising:
a chamber;
a substrate support installed in the chamber for supporting a substrate;
a target installed in the chamber, the target comprising a target material to be deposited on the substrate and a target support supporting the target material;
a first power supplier providing a negative voltage to the target support;
a mask spaced apart from the substrate to mask the peripheral portion of the substrate;
a shield shielding a peripheral portion of the substrate support from deposition from the target material, the shield connected to ground;
an electrical insulating member linking the mask and the shield and electrically insulating the mask from the shield; and
a short-circuit detecting apparatus connected to the mask, the short-circuit detecting apparatus including a second power supplier to supply a predetermined power to the mask during a non-discharge period and detecting the short-circuit of the mask by measuring a voltage drop or a current change between the mask and the second power supplier.

14. The sputtering apparatus of claim 13, wherein the short-circuit detecting apparatus further comprises a switch turned on to electrically connect the second power supplier and the mask during a discharge period of the sputtering apparatus and turned off to electrically disconnect the power supplier and the mask during the non-discharge period of the sputtering apparatus.

15. A sputtering apparatus comprising:
a chamber;
a substrate support installed in the chamber for supporting a substrate;
a target installed in the chamber, the target comprising a target material to be deposited on the substrate and a target support supporting the target material;
a mask spaced apart from the substrate to mask the peripheral portion of the substrate;
a shield shielding a peripheral portion of the substrate support from deposition from the target material, the shield connected to ground;
an electrical insulating member linking the mask and the shield and electrically insulating the mask from the shield; and
a short-circuit detecting apparatus connected to the mask, the short-circuit detecting apparatus comprising:
a power supplier supplying a predetermined power to the mask;
a switch turned on to electrically connect the power supplier and the mask during a discharge period of the sputtering apparatus and turned off to electrically disconnect the power supplier and the mask during a non-discharge period of the sputtering apparatus; and
a detector detecting a voltage or a current between the mask and the power supplier during the non-discharge period to determine the short-circuit of the mask.

16. The sputtering apparatus of claim 15, wherein the short-circuit detecting apparatus directly measures a voltage charged to the mask during the discharge period to determine the short-circuit of the mask.

17. The sputtering apparatus of claim 15, further comprising a magnetron generating a magnetic field above the target material.

18. The sputtering apparatus of claim 15, wherein the detector comprises a predetermined resistor installed between the power supplier and the switch, and a voltmeter measuring a voltage drop of the voltage from the power supplier to the resistor.

19. The sputtering apparatus of claim 15, wherein the detector comprises an ammeter measuring the current flowing between the power supplier and the mask.

20. A method of forming a film on the substrate, comprising utilizing the sputtering apparatus of claim 15.
